(19) United States
(12) Patent Application Publication
(10) Pub. No.: US 2012/0301633 A1
(43) Pub. Date: Nov. 29, 2012

(54) METHOD OF PRODUCING GAS BARRIER LAMINATE

(75) Inventor: Tomoyuki KIKUCHI, Kanagawa (JP)

(73) Assignee: FUJIFILM CORPORATION, Tokyo (JP)

(21) Appl. No.: 13/571,999

(22) Filed: Aug. 10, 2012

Related U.S. Application Data
(62) Division of application No. 12/759,054, filed on Apr. 13, 2010.

(30) Foreign Application Priority Data
Apr. 13, 2009 (JP) 2009-096906

(51) Int. Cl. C23C 16/44; C23C 16/50; C23C 14/34

(52) U.S. Cl. 427/569; 204/192.12; 427/255.6

(57) ABSTRACT

A method of producing a gas barrier laminate comprises: the steps of forming an inorganic compound layer on a substrate by vapor-phase film deposition, applying surface roughening treatment to a surface of the inorganic compound layer, and subsequently forming an organic compound layer on the roughened surface of the inorganic compound layer by flash evaporation.

### CROSS REFERENCE TO RELATED APPLICATIONS

This application is a division of co-pending application Ser. No. 12/759,054 filed on Apr. 13, 2010, which claims foreign priority to Japanese Application No. 2009-096906 filed on Apr. 13, 2009. The entire content of each of these applications is hereby expressly incorporated by reference.

### BACKGROUND OF THE INVENTION

The present invention relates to a gas barrier laminate formed of superposed films and particularly to a gas barrier laminate having an excellent adhesion between an inorganic compound layer and an organic compound layer in the gas barrier laminate comprising an inorganic compound layer and an organic compound layer placed thereon and a method of producing the same.

A gas barrier layer (a water-vapor barrier film) is formed not only in such positions or parts requiring moisture resistance in various apparatuses and devices including optical devices, displays such as liquid-crystal displays and organic EL displays, semiconductor manufacturing apparatuses, and thin-film solar cells, but also in packaging materials used to package food, clothing, electronic components, etc. A gas barrier film having a gas barrier layer formed on a plastic film substrate made of, for example, PET is used in various applications including the foregoing applications.

Known gas barrier films include ones made of various materials such as silicon nitride, silicon oxide, silicon oxynitride and aluminum oxide. These gas barrier films are generally formed by vapor-phase film deposition techniques such as a plasma-enhanced CVD technique.

Also known is a gas barrier laminate formed of a plurality of layers such as organic compound layers and inorganic compound layers described above to provide still higher gas barrier properties and oxidation resistance (laminate type gas barrier film).

These gas barrier laminates are required to have a good adhesion between films (interlayer adhesion) to achieve a sufficient mechanical strength and gas barrier properties required. A high adhesion is required particularly in a roll-to-roll type apparatus wherein a film is formed as the substrate is fed and transported from a substrate roll holding a long length of substrate while the film-coated substrate is rewound into a roll, producing an interlayer stress in web handling including reel-out from the roll and reel-in.

However, where an organic compound layer is formed on an inorganic compound layer, the adhesion at the film interface is so week as to cause interlayer detachment.

Propositions have been made to solve these problems.

For example, JP 2000-235930 A describes a method of producing a gas barrier laminate forming an organic compound layer on an inorganic compound layer by flash evaporation, wherein prior to forming an organic compound layer, an inorganic compound layer is irradiated with plasma in so-called plasma treatment to improve adhesion between the inorganic compound layer and the organic compound layer.

JP 2006-95932 A describes a gas barrier laminate wherein a protective film composed of an organic compound is formed on an inorganic compound layer such as, for example, a silicon oxide film and a silicon nitride film, and a mixture of two or more kinds of (meth)acrylic compounds is formed into an organic compound layer by flash evaporation to enhance the affinity between the organic compound layer and the inorganic compound containing silicon and thereby improve the adhesion between the inorganic compound layer and the organic compound layer.

Plasma treatment is applied to improve adhesion by cleaning the surface or by applying hydrophilizing treatment whereby an OH group is attached to the surface.

However, when the surface of an inorganic compound layer is hydrophilized, it tends to absorb vapor easily, leading to reduced gas barrier properties (vapor barrier properties).

Gas barrier films generally used include a silicon nitride film, a silicon oxide film, or other inorganic compound films containing silicon. Inorganic compounds containing silicon are most stable when in the Si—O bond. Thus, oxidation of unbonded species takes place as time passes at the outermost surface of the film, causing the adhesion to decrease. Thus, plasma treatment or other like treatment causes adhesion to decrease although a certain degree of good adhesion may initially hold for a while.

In flash evaporation, as is known, film materials are evaporated and the vapor is attached to a substrate, and cooled/condensed to form a liquid film, which is cured by exposure to ultraviolet rays or electron beams to finally form a film. As a result, the cure retraction rate at the time of condensation is great and the adhesion is reduced by stress, increasing difficulties in achieving a higher adhesion.

In addition, when depositing a film formed of a mixture of two or more compounds as described in JP 2006-95932 A by flash evaporation, the difference in vapor pressure between the compounds makes it difficult to obtain a desired film composition. This reduces the function of improving the adhesion by increasing the affinity between the organic compound layer and the inorganic compound layer.

### SUMMARY OF THE INVENTION

It is an object of the present invention to solve the problems associated with the prior art described above and provide a method of producing a gas barrier laminate having an organic compound layer formed by flash evaporation on an inorganic compound layer, whereby an excellent adhesion is obtained between the organic compound layer and the inorganic compound layer although the organic compound layer is formed using flash evaporation that can be detrimental to obtaining a good adhesion, and a long-term adhesion can be assured even when oxidation progresses in the surface of the inorganic compound layer as time passes where the inorganic compound layer used is a silicon compound generally used to form a gas barrier film.

A method of producing a gas barrier laminate according to the invention comprises the steps of: forming an inorganic compound layer on a substrate by vapor-phase film deposition, applying surface roughening treatment to a surface of the inorganic compound layer, and subsequently forming an organic compound layer on the roughened surface of the inorganic compound layer by flash evaporation.

A gas barrier laminate according to the invention comprises an inorganic compound layer formed by vapor-phase film deposition and having mean surface roughness Ra of 10 nm to 100 nm; and an organic compound layer formed on the inorganic compound layer by flash evaporation.

### BRIEF DESCRIPTION OF THE DRAWINGS

FIG. 1 is a schematic view showing a production device for implementing a gas barrier laminate production method according to an embodiment of the present invention.

FIG. 2 is a partial cross sectional view showing the gas barrier film produced by the embodiment of the present invention;

FIG. 3 is a partial cross sectional view showing a configuration of a substrate used in the gas barrier laminate production method of the embodiment of the present invention.

FIG. 4 is a view schematically showing an organic layer formation section in the production device shown in FIG. 1.

FIG. 5 is a schematic view showing a production device for implementing a gas barrier laminate production method according to a modified embodiment of the present invention.

### DETAILED DESCRIPTION OF THE INVENTION

Now, the method for producing a gas barrier laminate according to the present invention and the gas barrier laminate thereby produced will be described in detail by referring to the preferred embodiments shown in the accompanying drawings.

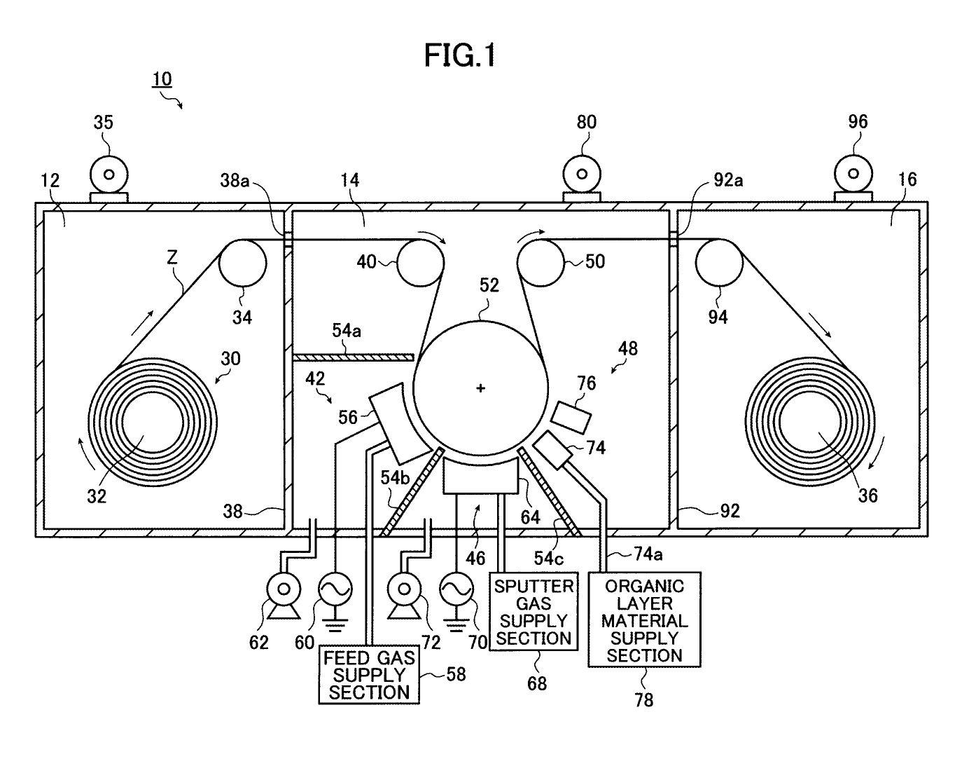

FIG. 1 is a schematic view showing an embodiment of the production device for implementing the gas barrier laminate production method of the present invention.

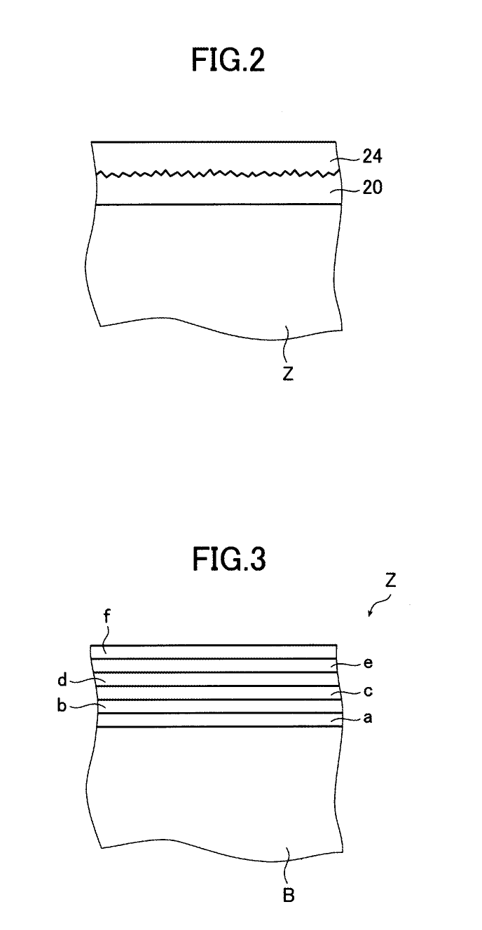

An illustrated embodiment of a gas barrier laminate production apparatus 10 produces a gas barrier film (or a material or an intermediate product of a gas barrier film) as conceptually shown in FIG. 2 by forming or depositing an inorganic compound layer 20 that exhibits gas barrier properties by a plasma CVD technique on the surface of a long length of substrate Z, a film material, as it travels in the longitudinal direction, then roughening the surface of the inorganic compound layer 20 by back-sputtering treatment to form an organic compound layer 24 on the roughened surface of the inorganic compound layer 20 by flash evaporation technique, thus forming a gas barrier laminate having the inorganic compound layer 20 and the organic compound layer 24 formed on the surface of the substrate Z.

This production device 10 is a roll-to-roll type film deposition device whereby the substrate Z is fed from a substrate roll 30 having a long length of substrate Z wound into a roll, a gas barrier laminate comprising the inorganic compound layer 20 and the organic compound layer 24 is formed on the substrate Z traveling in the longitudinal direction, and the substrate Z having the gas barrier layer formed thereon, i.e., the gas barrier film, is wound into a roll.

In the production method of the present invention, examples of the substrate (substrate for film deposition) that may be preferably used include, in addition to one in the form of a long length of sheet as in the illustrated case, various articles (members/base materials) including a film cut into a sheet with a predetermined length (i.e., cut sheet), optical devices such as lenses and optical filters, photoelectric transducers such as organic EL devices and solar sells, and display panels such as liquid-crystal displays and electronic paper.

The material of the substrate is also not particularly limited, and various materials may be used, provided that a gas barrier layer can be formed by plasma-enhanced CVD technique. The substrate may be made of organic materials such as plastic films (resin films) or of inorganic materials such as metals and ceramics.

The present invention is advantageously used to produce a gas barrier film as in the illustrated case, and sheet-like substrates (plastic films) made of organic substances such as polyethylene terephthalate (PET), polyethylene naphthalate (PEN), polyethylene, polypropylene, polystyrene, polyamide, polyvinyl chloride, polycarbonate, polyacrylonitrile, polyimide, polyacrylate, and polymethacrylate are used with advantage.

In the present invention, base materials such as plastic films and lenses having layers (films) formed thereon to impart various functions may be used for the substrate. Exemplary layers include a protective layer, an adhesive layer, a light-reflecting layer, a light-shielding layer, a planarizing layer, a buffer layer, and a stress-relief layer.

The substrate Z used may be one having a single layer formed on a base material or one having a plurality of layers such as layers a to f formed on a base material B as conceptually shown in FIG. 3.

In the substrate Z having one or more than one layer formed on the base material B, two of the layers (e.g., the layers b and c in FIG. 3) may be a gas barrier laminate of the invention formed by the production method of the invention or may be the substrate Z formed of a plurality of the gas barrier laminates (which may be repetitions) of the invention formed according to the production method of the invention.

In cases where the surface of the substrate has irregularities or foreign substances having considerably larger sizes than the thickness of the gas barrier layer, the gas barrier properties deteriorate, making it impossible to obtain desired gas barrier properties even if high oxidation resistance is achieved.

Therefore, the substrate used is preferably one which has a sufficiently smooth surface and to which few foreign substances adhere.

As described above, the production device 10 shown in FIG. 1 is a so-called roll-to-roll type film deposition device in which the substrate Z is fed from the substrate roll 30 having a long length of substrate Z wound into a roll, a gas barrier laminate is formed on the substrate Z traveling in the longitudinal direction and the substrate Z having the gas barrier layer formed thereon is rewound into a roll. The production device 10 includes a feed chamber 12, a film deposition chamber 14 and a take-up chamber 16.

In addition to the illustrated members, the production device 10 may also have various members with which film deposition devices that perform film deposition by plasma-enhanced CVD are provided including sensors, and members (transport means) for transporting the substrate Z along a predetermined path, as exemplified by a transport roller pair and guide members for regulating the position in the width direction of the substrate Z.

The feed chamber 12 includes a rotary shaft 32, a guide roller 34 and a vacuum evacuation means 35.

The substrate roll 30 into which a long length of substrate Z is wound is mounted on the rotary shaft 32 in the feed chamber 12.

Upon mounting of the substrate roll 30 on the rotary shaft 32, the substrate Z travels along a predetermined travel path starting from the feed chamber 12 and passing through the film deposition chamber 14 to reach a take-up shaft 36 in the take-up chamber 16.

In the production device 10, feeding of the substrate Z from the substrate roll 30 and winding of the substrate Z on the take-up shaft 36 in the take-up chamber 16 are carried out in synchronism to sequentially achieve formation of the inorganic compound layer 20 on the substrate Z, surface roughening applied to the surface of the inorganic compound layer 20 by back-sputtering treatment, and formation of the organic compound layer 24 in the film deposition chamber 14 as the long length of substrate Z travels in its longitudinal direction along the predetermined travel path.

In the preferred embodiment of the illustrated production device 10, the feed chamber 12 and the take-up chamber 16 are provided with vacuum evacuation means 35 and 96, respectively. The vacuum evacuation means are provided in these chambers to ensure that these chambers have the same degree of vacuum (pressure) during film deposition as the film deposition chamber 14 described later so that the pressures inside these neighboring chambers do not affect the degree of vacuum inside the film deposition chamber 14 (deposition of the gas barrier film).

The vacuum evacuation means 35 is not particularly limited, and exemplary means that may be used include vacuum pumps such as a turbo pump, a mechanical booster pump, a rotary pump and a dry pump, an assist means such as a cryogenic coil, and various other known (vacuum) evacuation means that use a means for adjusting the ultimate degree of vacuum or the amount of air discharged and which are employed in vacuum deposition devices. The same applies to the other vacuum evacuation means described later.

The present invention is not limited to the embodiment in which all the chambers are provided with vacuum evacuation means, and the feed chamber 12 and the take-up chamber 16 which require no vacuum evacuation treatment may not be provided with vacuum evacuation means. However, in order to minimize the adverse effects of the pressures in these chambers on the degree of vacuum in the film deposition chamber 14, the size of the slit 32 through which the substrate Z passes may, for example, be reduced to a minimum, or a subchamber may be provided between the adjacent chambers to provide a reduced internal pressure in the subchamber.

Even in the illustrated production device 10 in which all the chambers have the vacuum evacuation means, it is preferable to minimize the size of the portion, such as the slit 38a, through which the substrate Z passes.

The substrate Z is guided by the guide roller 34 and fed into the film deposition chamber 14 that is separated from the feed chamber 12 by a separation wall 38. In the film deposition chamber 14 are sequentially performed, as described above, formation of the inorganic compound layer 20 on the substrate Z, surface roughening of the inorganic compound layer 20 through back-sputtering treatment, and formation of the organic compound layer 24 on the incoming substrate Z.

The film deposition chamber 14 comprises a guide roller 40, an inorganic compound layer formation section 42 (referred to below as inorganic layer formation section 42), a surface roughening section 46, an organic compound layer formation section 48 (referred to below as organic layer formation section 48), a guide roller 50, and a drum 52. The inorganic layer formation section 42 is kept in a substantially air-tight isolation by separation walls 54a and 54b; the surface roughening section 46 is kept in a substantially air-tight isolation by separation walls 54b and 54c.

The drum 52 in the film deposition chamber 14 is a cylindrical member that turns about its central axis counterclockwise as seen in the drawing. The substrate Z guided by the guide roller 40 along the predetermined path is passed over a predetermined region of the peripheral surface of the drum 52 and thus held in a predetermined position as it travels in the longitudinal direction to pass the inorganic layer formation section 42, the surface roughening section 46, and the organic layer formation section 48 sequentially before reaching the guide roller 50.

The drum 52 also serves as a counter-electrode to form an electrode pair with a shower head electrode 56 in the inorganic layer formation section 42 and a shower head electrode 64 in the surface roughening section 46, both described later. To this end, the drum 52 is connected to a bias power source or grounded (connection is not shown in either case). Alternatively, the drum 52 may be capable of switching between connection to the bias power source and grounding.

The drum 52 also acts as temperature adjusting means for agglomeration of a sprayed liquid of the organic compound, restriction of increase in temperature of the substrate in film deposition process, and the like in the organic layer formation section 48. Thus, the drum 52 contains a temperature adjusting means. The temperature adjusting means of the drum 52 is not particularly limited, and various types of temperature adjusting means including one in which a refrigerant is circulated and a cooling means using a piezoelectric element are all available for use.

The inorganic layer formation section 42 forms the inorganic compound layer 20 (referred to as inorganic layer 20 below) on the surface of the substrate Z by a vapor-phase film deposition technique. In the illustrated embodiment, the inorganic layer formation section 42 forms (deposits) the inorganic layer 20 by capacitively coupled plasma enhanced chemical vapor deposition (CCP-CVD).

The plasma-enhanced CVD used in the present invention is not limited to CCP-CVD as in the illustrated case, and various types of plasma-enhanced CVD are all available for use including inductively coupled plasma-enhanced CVD (ICP-CVD), microwave plasma CVD, electron cyclotron resonance CVD (ECR-CVD) and atmospheric pressure barrier discharge CVD. A catalytic CVD (Cat-CVD) technique may also be used for the purpose. Further, the inorganic layer 20 may be formed according to the invention not only by the plasma-enhanced CVD but by any of vapor-phase film deposition techniques such as sputter deposition and vacuum vapor deposition. Plasma-enhanced CVD techniques, in particular, may be advantageously used.

Basically, the inorganic layer formation section 42 in the illustrated embodiment uses a known CCP-CVD technique to form the inorganic layer 20 and comprises the shower head electrode 56, a feed gas supply section 58, an RF power source 60, and a vacuum evacuation means 62.

The shower head electrode 56 is of a known type used in film deposition by CCP-CVD.

In the illustrated embodiment, the shower head electrode 56 is, for example, in the form of a hollow, substantially rectangular solid and is disposed so that its largest surface faces the peripheral surface of the drum 52 and the perpendicular from the center of the largest surface coincides with the normal to the peripheral surface of the drum 52. A large number of through holes are formed in the whole surface of the shower head electrode 56 facing the drum 52. In a preferred embodiment, the surface of the shower head electrode 56 facing the drum 52 is so curved as to contour the peripheral surface of the drum 52.

In the illustrated embodiment, one shower head electrode (film deposition means using CCP-CVD) is provided in the inorganic layer formation section 42. However, this is not the sole case of the present invention and a plurality of shower head electrodes may be disposed in the direction of travel of the substrate Z. The same applies when using other types of plasma-enhanced CVD techniques than CCP-CVD. For example, when a gas barrier film is formed or manufactured by ICP-CVD, a plurality of (induction) coils for forming an induced electric field (induced magnetic field) may be provided along the direction of travel of the substrate Z.

The present invention is not limited to the case in which the inorganic layer is formed by an ICP-CVD technique using the shower head electrode; the gas barrier layer may be formed by using a common electrode in plate form and a gas supply nozzle.

The feed gas supply section 58 is of a known type used in vacuum deposition devices such as plasma CVD devices, and supplies a feed gas into the shower head electrode 56.

As described above, a large number of through holes are formed in the surface of the shower head electrode 56 facing the drum 52. Therefore, the feed gas supplied into the shower head electrode 56 passes through the through holes and are introduced into the space between the shower head electrode 56 and the drum 52.

According to the invention, the inorganic layer 20 may be any layer formed of any of various inorganic compounds exhibiting gas barrier properties (steam barrier properties) including but not limited to silicon oxide, silicon nitride, silicon oxynitride, silicon oxynitrocarbide, and aluminum oxide.

Of these, silicon nitride and silicon oxide are preferred.

Thus, the gas supplied from the feed gas supply section 58 may be a known feed gas matching the inorganic layer 20 to be formed.

For example, silane gas, ammonia gas, and/or nitrogen gas may be supplied to the shower head electrode 56 when it is a silicon nitride film that is to be formed as the inorganic layer 20; silane gas and oxygen gas may be supplied when it is a silicon oxide film that is to be formed; and silane gas, ammonia gas and/or nitrogen gas, and oxygen gas may be supplied when it is a silicon oxynitride film that is to be formed.

Where necessary, the feed gas may be inert gases such as Ar gas, He gas, Ne gas, Kr gas, Xe gas, Rn gas and N₂ gas used in combination with the above gases.

The RF power source 60 supplies plasma excitation power to the shower head electrode 56. The RF power source 60 may be any of known RF power sources used in various plasma CVD devices.

In addition, the vacuum evacuation means 62 evacuates the inorganic layer formation section 42, i.e., the closed space defined by the separation wall 54a, the separation wall 54b, and the peripheral surface of the drum 52, to keep it at a predetermined film deposition pressure in order to form the gas barrier layer by plasma-enhanced CVD, and is of a known type of vacuum evacuation means used in vacuum deposition devices as described above.

The conditions under which the inorganic layer 20 is formed such as the feed gas flow rate and the film deposition pressure may be appropriately set without any specific limitation in accordance with the kind and thickness of the inorganic film 20 to be formed, the feed gas used, and a targeted film deposition rate, and the like.

The thickness of the inorganic layer 20 according to the invention may be appropriately set without any specific limitation according to such conditions as the applications for which the gas barrier laminate is intended, the required gas barrier properties, the kinds of the inorganic layer 20 and the organic layer 24 to be formed. The thickness of the inorganic layer 20 is preferably 10 nm to 200 nm.

When the inorganic layer 20 has a thickness in that range, favorable results will be obtained in terms of gas barrier properties, increase in substrate transport speed used in film deposition, etc.

In the production method of the present invention, the gas barrier film is preferably formed with the substrate temperature adjusted to 120° C. or less. It is particularly preferable to form the gas barrier film with the temperature of the substrate adjusted to 80° C. or less.

By adjusting the temperature of the substrate to 120° C. or less, preferable results are obtained in that a gas barrier film having advantageously high barrier properties and oxidation resistance and a low-stress gas barrier film can be formed on a less heat-resistant plastic film substrate such as a PEN substrate or on a substrate using a less heat-resistant organic material as the base material. In addition, by adjusting the temperature of the substrate to 80° C. or less, preferable results are obtained in that a gas barrier film having advantageously high barrier properties and oxidation resistance and a low-stress gas barrier film can be formed on a less heat-resistant plastic film substrate such as a PET substrate.

The surface roughening section 46 subjects the inorganic layer 20 formed in the inorganic layer formation section 42 to back-sputtering treatment to roughen the surface of the inorganic layer 20 and comprises the shower head electrode 64, a sputter gas supply section 68, a DC pulse power source 70, and a vacuum evacuation means 72.

The shower head electrode 64 and the sputter gas supply section 68 are basically equivalent to the shower head electrode 56 and the feed gas supply section 58 provided in the inorganic layer formation section 42. The DC pulse power source 70 is a known DC pulse power source used for a sputtering device and the like. The surface roughening section 46 may use an RF power source similar to the power source provided in the inorganic layer formation section 42 in lieu of the DC power source 70.

The surface roughening section 46 basically roughens the surface of the inorganic layer 20 by a known back-sputtering treatment. Specifically, the sputter gas supply section 68 supplies a sputter gas to the shower head electrode 64 with the inside of the surface roughening section 46 (the closed space defined by the separation wall 54b, the separation wall 54c, and the peripheral surface of the drum 52) kept at a predetermined pressure by the vacuum evacuation means 72 to introduce the sputter gas onto the surface of the substrate Z or the space between the surface of the inorganic layer 20 and the shower head electrode 64, while the DC pulse power source 70 supplies plasma excitation power to the shower electrode 64 and, optionally, applies a negative voltage to the drum 52. Thus, positive ions are generated from the sputter gas between the inorganic layer 20 and the surface of the shower head electrode 64, and the positive ions impinge on the surface of the inorganic layer 20 to roughen the surface of the inorganic layer 20.

The sputter gas (sputtering gas) used is not specifically limited and is preferably one or more gases selected from the group consisting of Ar gas, He gas, Ne gas, Kr gas, Xe gas, Rn gas and N₂ gas.

The sputter gas may be supplied in an amount that, while not specifically limited, may be appropriately set according to the kind of the inorganic layer 20, the targeted surface roughness of the inorganic layer 20, and the like and is preferably in a range of 20 ml/min to 50 ml/min to permit a consistent surface roughening treatment intended or for other reasons.

The back-sputtering treatment may be applied under a pressure that, while not specifically limited, may be appropriately set according to the gas used, the kind of the inorganic layer 20, the targeted surface roughness of the inorganic layer 20, and the like and is preferably in a range of 0.3 Pa to 10 Pa, especially 2 Pa, to permit a consistent surface roughening treatment intended or for other reasons.

The back-sputtering treatment may be applied with a plasma excitation power that, while not specifically limited, may be appropriately set according to the gas used, the kind of the inorganic layer 20, the targeted surface roughness of the inorganic layer 20, and the like and is preferably in a range of 10 W to 100 W to permit a consistent surface roughening treatment intended or for other reasons.

Where the power source used is a DC pulse power source, a potential of −20 V to −10 V is preferably applied to the shower head electrode 64 (the electrode provided for sputtering) to intensify the impingement of the sputter gas ions.

The back sputtering treatment (surface roughening treatment) is preferably adjusted so that the surface of the inorganic layer 20 is roughened to mean surface roughness Ra of 10 nm to 100 nm.

According to the invention, an organic compound layer 24 (referred to below as organic layer 24) is formed on the inorganic layer 20 by a flash evaporation technique as will be described in detail. The surface roughening treatment, when adjusted to roughen the surface of the inorganic layer 20 to mean surface roughness Ra of 10 nm to 100 nm, increases the surface area of an organic compound agglomerated by the flash evaporation and thus produces significantly good anchor effects, which further increase the adhesion between the inorganic layer 20 and the organic layer 24.

The back sputtering treatment is more preferably adjusted to roughen the surface of the inorganic layer 20 to mean surface roughness Ra of 10 nm to 50 nm. While the surface roughening treatment slightly reduces the gas barrier properties of the inorganic layer 20, the surface roughness of the inorganic layer 20 held in this range not only favorably improves the adhesion as described above but curbs the decrease of the gas barrier properties, making it possible to obtain a gas barrier laminate having good gas barrier properties more consistently.

The surface roughening treatment applied to the inorganic layer 20 in the gas barrier laminate production method of the invention may be achieved not only by back sputtering treatment but by any of various surface roughening treatment means including dry etching, wet etching, and transfer technique, provided that the surface of the inorganic layer 20 can be roughened to targeted conditions.

The organic layer formation section 48 forms or deposits the organic layer 24 on the surface of the surface-roughened inorganic layer 20 by flash evaporation and comprises an organic layer material evaporation means 74, a curing section 76, an organic layer material supply section 78, and a vacuum evacuation means 80.

The vacuum evacuation means 80 evacuates the film deposition chamber 14 so that the pressure in the film deposition chamber 14 matches the flash evaporation effected in the organic layer formation section 48.

The organic layer material supply section 78 evaporates the monomers of a liquid organic compound (or a coating material formed by dissolving the monomers of an organic compound in a solvent) and supply the organic layer material evaporation means 74 with the organic compound vapor thus produced through a pipe 74a.

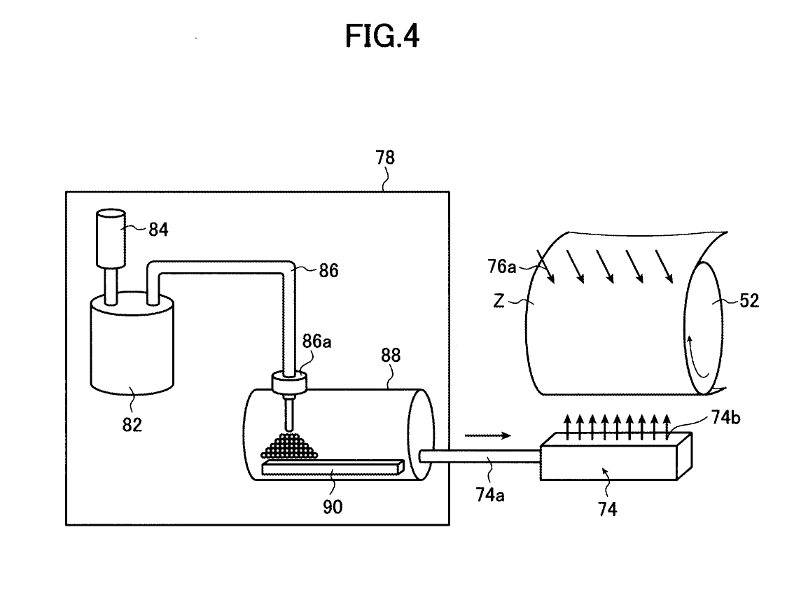

As conceptually shown in FIG. 4, the organic layer material supply section 78 has a liquid organic compound stored therein and is kept under a given reduced pressure. It comprises a tank 82 provided with an evacuation means for reducing the inside of the tank 82 to a given pressure and an agitation means, a syringe pump 84, and a liquid-propelling section (heat chamber) 88 connected with the tank 82 through a pipe 86.

The liquid organic compound in the tank 82 is agitated by the agitation means under a reduced pressure for defoaming or removal of unnecessary gases. The organic compound is supplied under pressure applied by the syringe pump 84 from the tank 82 to the liquid-propelling section 88. The syringe pump pressure and the liquid supply rate of the syringe pump 84 may be appropriately determined according to such conditions as the thickness of the organic layer 24 to be formed and the kind of the organic layer 24 and are preferably 50 PSI to 300 PSI and 0.1 ml/min to 10 ml/min, respectively.

In the illustrated example, the liquid-propelling section 88 has the shape of a hollow cylinder and comprises a heating plate 90 in it. The liquid-propelling section 88 is provided with an evacuation means for evacuating the inside thereof and a heating means for heating the heating plate 90, both not shown.

The liquid-propelling section 88 comprises a droplet injection port 86a at a joint with the pipe 86. The droplet injection port 86a comprises an ultrasonic wave application means and a cooling means, both not shown.

In the liquid-propelling section 88, the liquid organic compound supplied under pressure from the syringe pump 84 is reduced to droplets at the droplet injection port 86a to which ultrasonic pressure is applied and sprayed onto the heating plate 90. The power output of the ultrasonic wave used here is not specifically limited and is preferably in a range of 1 W to 10 W to permit spray of yet smaller droplets or for other reasons.

The organic compound in the form of droplets evaporates when it comes into contact with the heating plate 90 to become a vapor. The organic compound in the form of a vapor is supplied through a pipe 74a to the organic layer material evaporation means 74.

Reduction of the liquid organic compound to fine particles by application of ultrasonic wave increases the evaporation efficiency of the organic compound. The injection port 86a is preferably kept at a temperature in a range of 5° C. to 50° C. by the cooling means to prevent thermal cure of the organic compound due to quick temperature rise of the injection port 86a caused by application of ultrasonic wave thereto.

The heating plate 90 is preferably kept at a temperature in a range of 150° C. to 300° C. for a favorable evaporation efficiency of the liquid organic compound. The liquid-propelling section 88 is preferably kept at a pressure in a range of 2×10⁻³ Pa to 1×10⁻² Pa to ensure efficient supply of the vapor to the liquid-propelling section or the organic layer material evaporation means 74.

The organic layer material evaporation means 74 sprays the vapor of the monomers of the organic compound to be formed into the organic layer 24 supplied from the organic layer material supply section 78 onto the surface of the substrate Z that is passed over the drum 52, i.e., the surface-roughened inorganic layer 20, allowing the vapor to agglomerate.

It is the differential pressure between the liquid-propelling section 88 and the organic layer formation section 48 (or film deposition chamber 14) that enables the transfer of the vapor from the liquid-propelling section 88 to the organic layer material evaporation means 74 and the spray of the vapor from the organic layer material evaporation means 74.

The organic layer material evaporation means 74 is provided with a heat control means not shown that includes a heating nozzle 74b for heating the environment to a temperature ranging an agglomeration temperature to an evaporation temperature.

The vapor of the monomers supplied from the organic layer material supply section 78 passes through the heating nozzle 74b and a given amount thereof agglomerates onto the substrate Z. The heating nozzle 74b is preferably kept at a temperature of 150° C. to 300° C.

To increase the agglomeration efficiency, the drum 52 is preferably cooled to keep the substrate Z at a temperature of say −15° C. to 25° C.

The curing section 76 cures the organic compound agglomerated on the substrate Z to form it into the organic layer 24. The curing section 76 may be formed using, for example, a UV radiation means for radiating UV light (ultraviolet light) 76a (see FIG. 4). The UV radiation means preferably has a UV illuminance of 10 mW/cm² to 100 mW/cm².

The curing section 76 may be formed using an electron radiation means for radiating electron beams or a microwave radiation means for radiating microwaves.

The inorganic layer 20 formed by a vapor-phase film deposition technique such as plasma-enhanced CVD and sputtering generally has mean surface roughness Ra of 0.1 nm to 9 nm, offering a high surface smoothness. It was supposed in the conventional art that when forming an organic layer on an inorganic layer, the adhesion was improved by taking advantage of such a surface smoothness and cleaning the surface to a maximum by plasma treatment or the like as described, for example, in JP 2000-235930 A.

According to the study by the present inventor, however, the inorganic layer obtained by a vapor-phase film deposition technique often fails, because of the high surface smoothness, to offer a sufficient adhesion and exhibits poor wetting properties in coating and flash evaporation processes. In addition, because, according to the flash evaporation technique, evaporated film material is caused to attach to a surface intended for film deposition, and cooled and condensed to form a film or a material film for film formation, which material film is cured by exposure to ultraviolet light or the like, the film thus obtained has such a great cure retraction rate at condensation and the adhesion is reduced by stress, making it difficult to achieve an enhanced adhesion.

In contrast, the organic layer 24 is formed, according to the present invention, by flash evaporation after the surface of the inorganic layer 20 is roughened by, for example, back-surface roughening treatment (preferably to mean surface roughness Ra of 10 nm to 100 nm) in the gas barrier laminate production wherein the organic layer 24 is formed on the inorganic layer 20 by a vapor-phase film deposition technique.

This surface roughening treatment increases the surface area of the organic compound agglomerated by the flash evaporation, and the roughened surface of the inorganic layer 20 admits the organic compound in the asperity of the surface, producing good anchor effects to further increase the adhesion between the inorganic layer 20 and the organic layer 24.

The organic layer 24 formed on the surface-roughened inorganic layer 20 is not specifically limited and may be any of a layer formed of an organic compound capable of providing any of various functions desired, including a protective layer, an adhesive layer, a light-reflecting layer, a light-shielding layer, a planarizing layer, a buffer layer, and a stress-relief layer.

The material of the inorganic layer 24 is not specifically limited and may be selected for use as appropriate from organic compounds according to intended functions of the organic layer 24. The organic compound used to form the organic layer 24 include polymers such as acrylic resin or methacrylic resin, polyester, methacrylic acid—maleic acid copolymer, polystyrene, transparent fluororesin, polyimide, fluorinated polyimide, polyamide, polyamideimide, polyetherimide, cellulose acylate, polyurethane, polyetherketone, polycarbonate, polycarbonate modified with fluorene ring, polycarbonate modified with an alicycle, and polyester modified with fluorene ring. These high-molecular compounds or polymers composed of monomer mixtures are obtained by polymerizing monomer mixtures.

A preferred polymer for forming the organic layer 24 is an acrylic resin or a methacrylic resin having a polymer composed of an acrylate and/or methacryolate monomer as a major component.

Specific examples of acrylates and methacrylates preferably used for forming the organic layer 24 according to the invention are given below as illustrative but not limitative examples of the present invention.

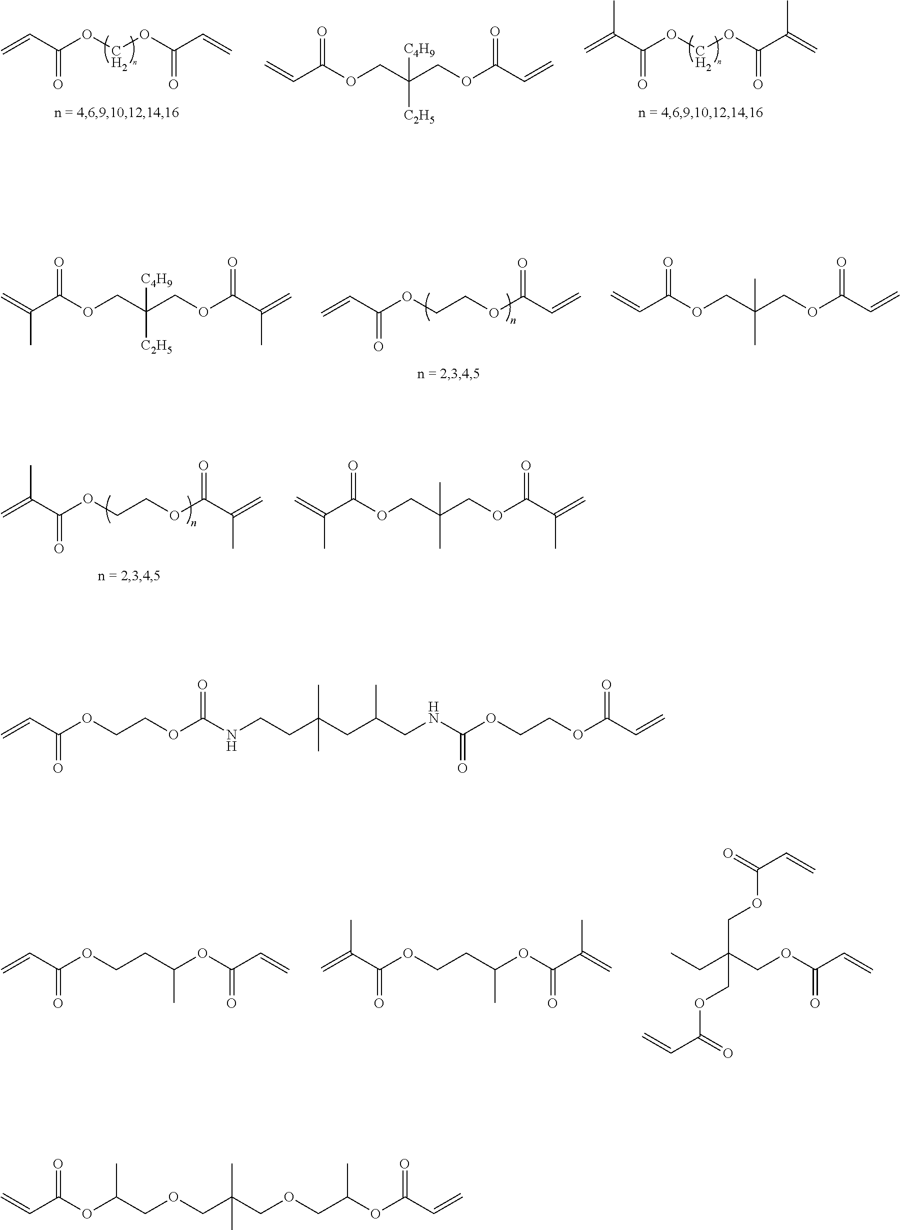

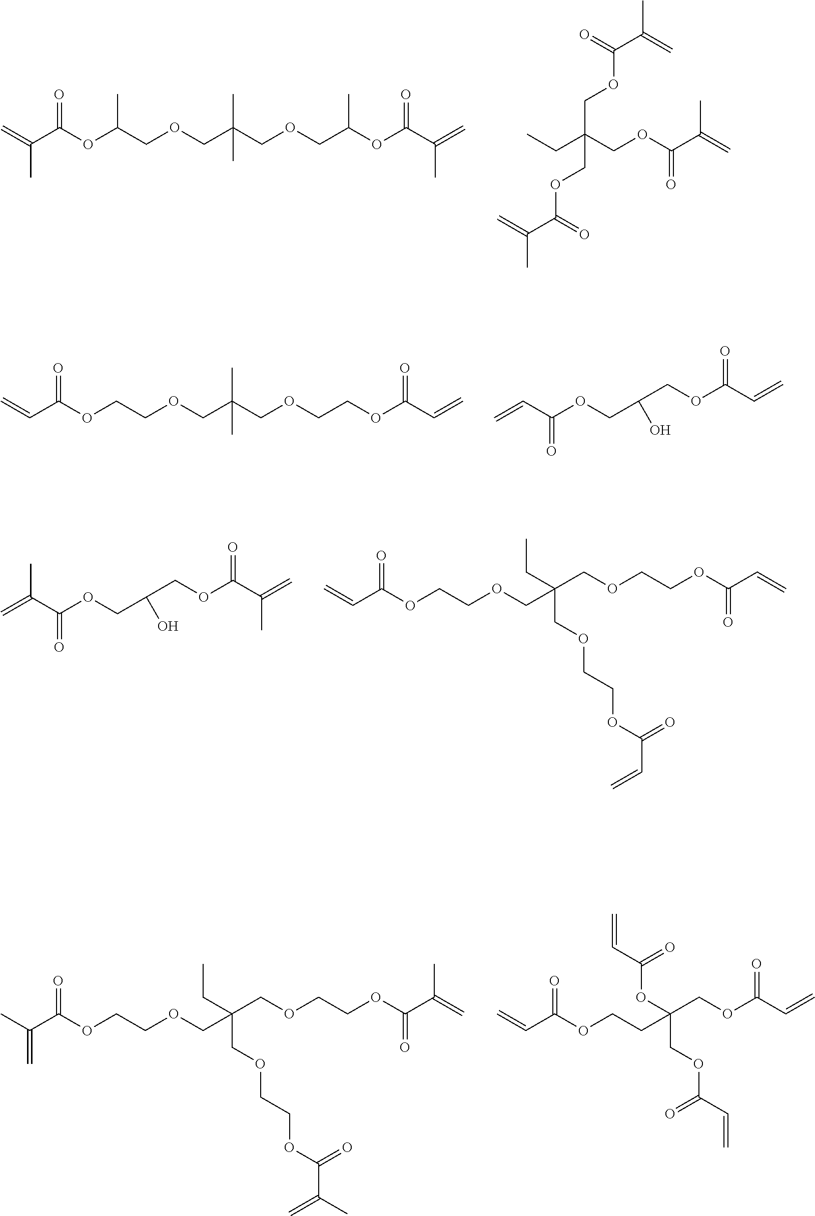

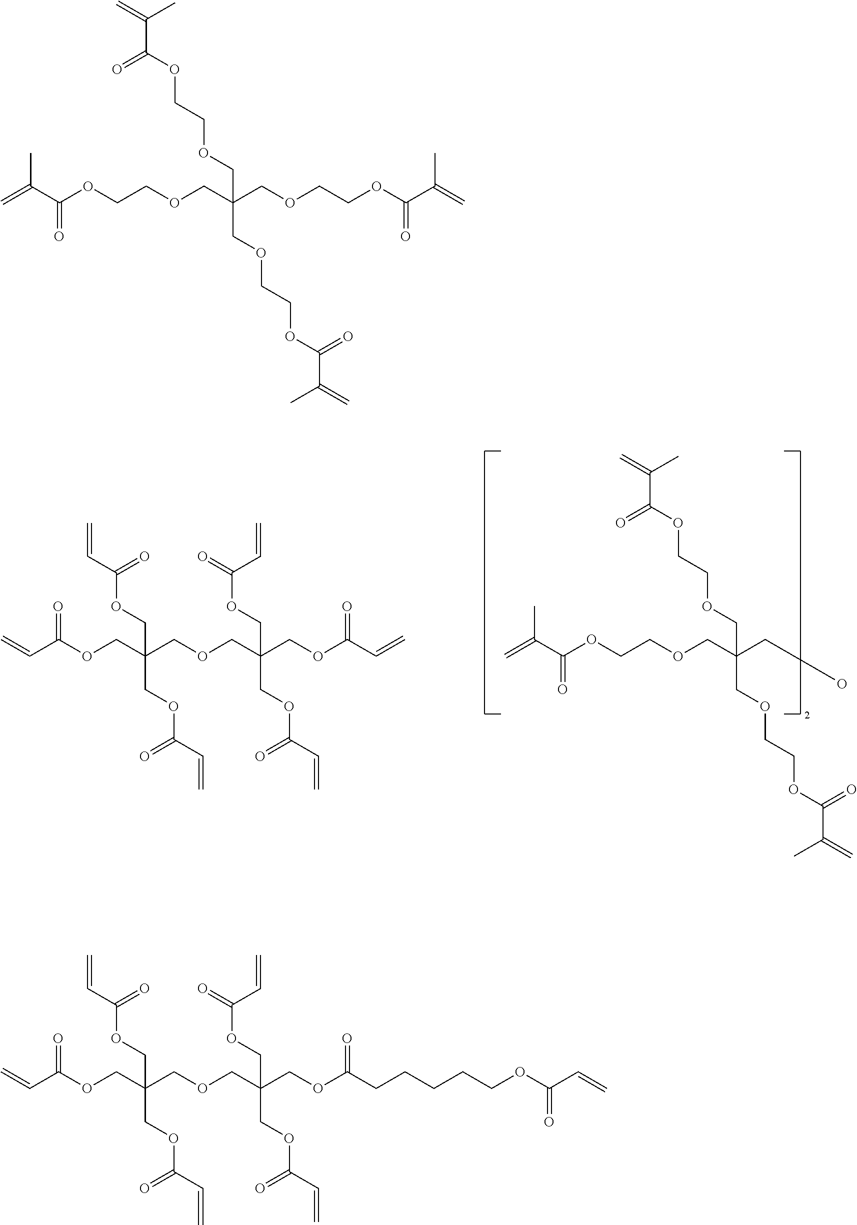

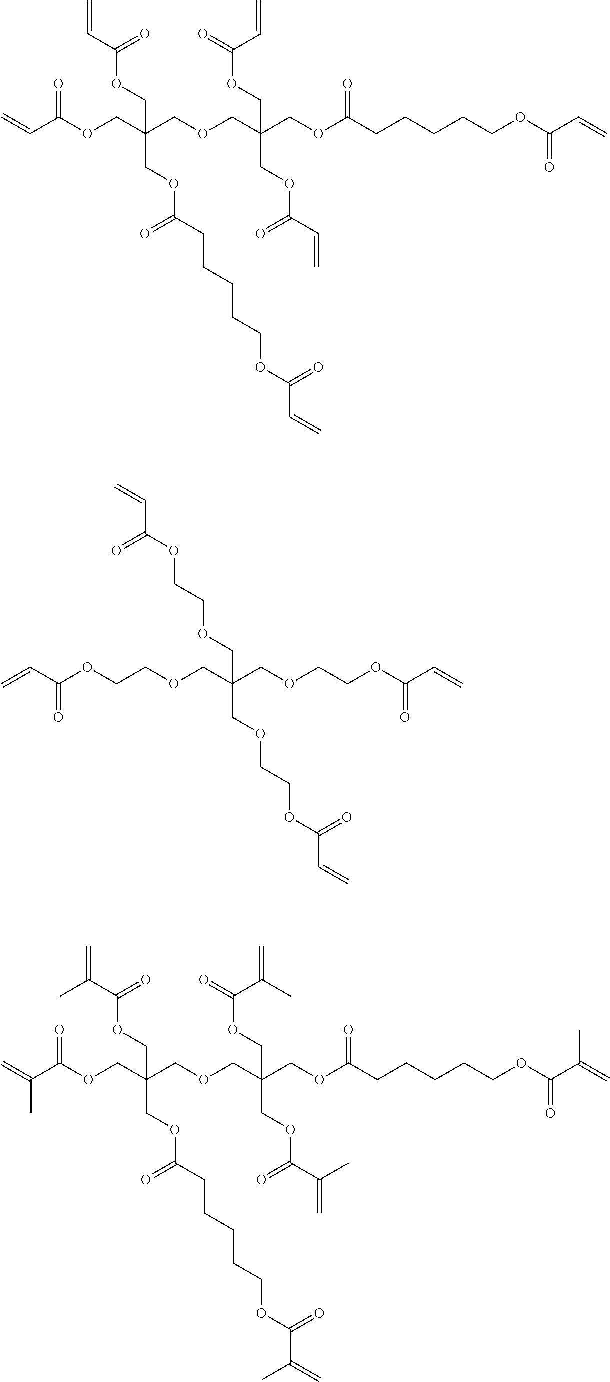

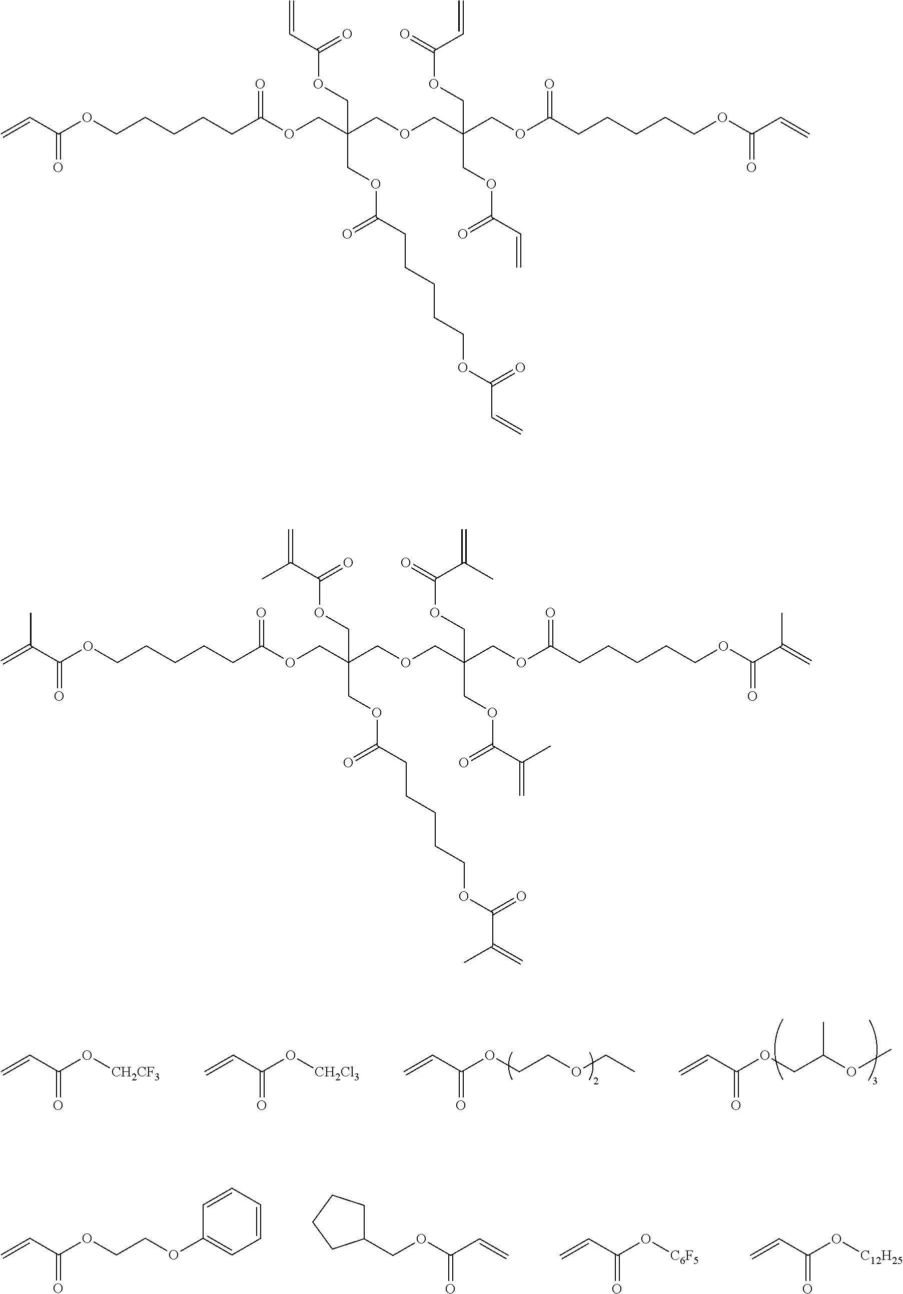

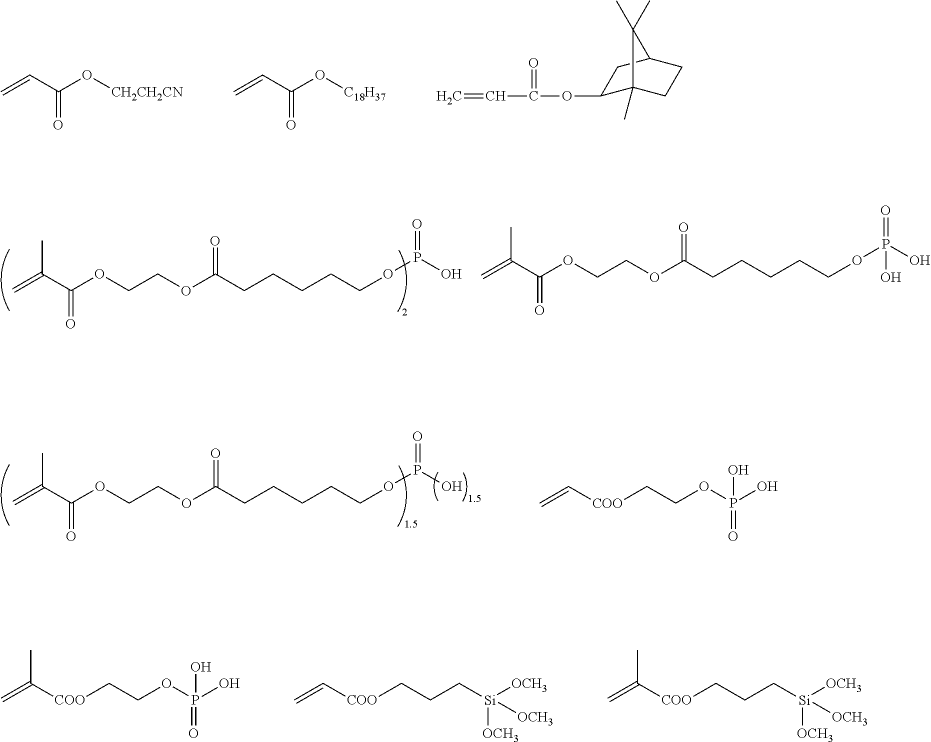

The thickness of the organic layer 24 according to the invention may be appropriately set without any specific limitation according to such conditions as the applications for which the gas barrier laminate is intended and the required gas barrier properties. The thickness of the inorganic layer 20 is preferably 100 nm to 700 nm.

When the inorganic layer 24 has a thickness in that range, favorable results will be obtained in coating of defects existent in the surface of the substrate Z, the surface smoothness of the organic layer 24, etc.

The substrate Z passed over the drum 52 travels in the longitudinal direction to sequentially undergo formation of the inorganic layer 20 in the inorganic layer formation section 42, surface roughening treatment applied to the surface of the inorganic layer 20 in the surface roughening section 46, and formation of the organic layer 24 on the surface of the inorganic layer 20 in the organic layer formation section 48 before being guided by the guide roller 50 to enter the take-up chamber 16.

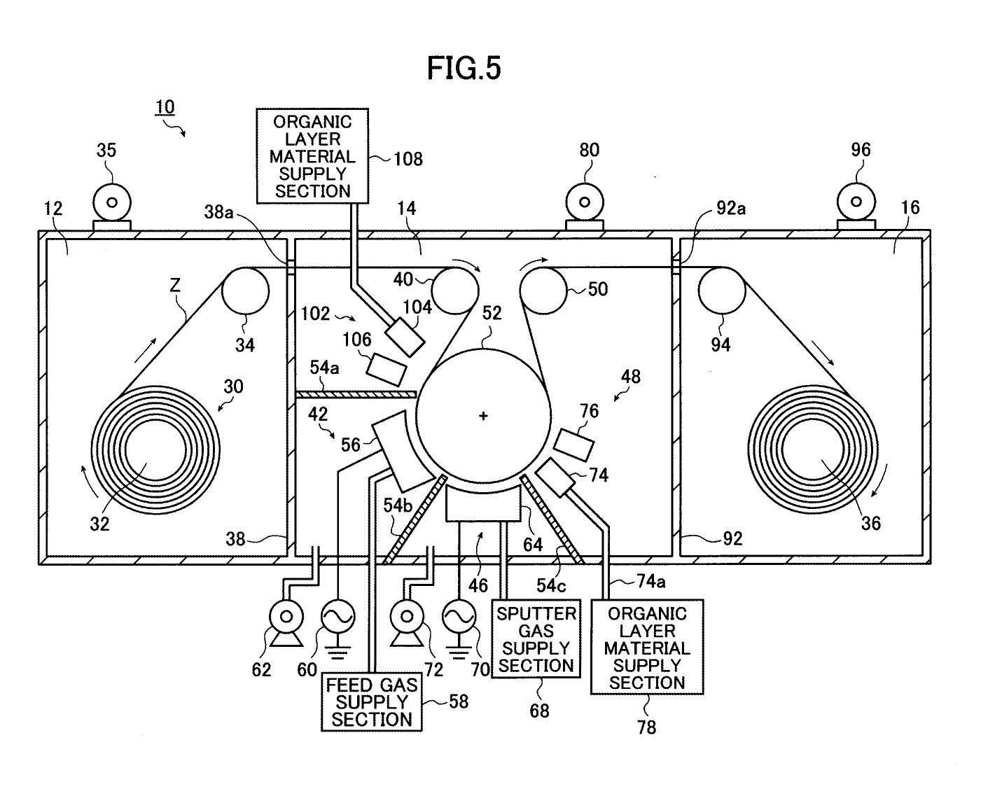

As shown in FIG. 5, an organic layer formation section 102 using flash evaporation may be provided upstream of the inorganic layer formation section 42. The organic layer formation section 102 comprises an organic layer material evaporation section 104, a curing section 106 and an organic layer material evaporation section 108 connected to the organic layer material evaporation section 104. In that case, an organic layer is first formed on the surface of the substrate Z, and the inorganic layer 20 is formed on that organic layer in the inorganic layer formation section 42, whereupon surface roughening treatment is applied to the surface of the inorganic layer 20, thereafter forming the organic layer 24 on the surface roughened organic layer 20.

Now, the present invention will be described in more detail by describing the formation of the gas barrier laminate in the film deposition chamber 14.

As described above, upon mounting of the substrate roll 30 on the rotary shaft 32, the substrate Z is reeled out from the substrate roll 30 and travels along the predetermined travel path along which the substrate film Z in the feed chamber 12 is guided by the guide roller 34 to reach the film deposition chamber 14, where the substrate Z is guided by the guide roller 40, passed over a predetermined region of the peripheral surface of the drum 52 and guided by the guide roller 42 to reach the take-up chamber 16, where the substrate Z is guided by a guide roller 94 to reach the take-up shaft 36.

The drum 52 is kept at a given temperature by a temperature control means.

The substrate Z fed from the feed chamber 12 and guided by the guide roller 40 along the predetermined path travels on the predetermined travel path as it is supported/guided by the drum 52.

The organic layer formation section 48 (the inside of the film deposition chamber 14) is reduced by the vacuum evacuation means 80 to a given degree of vacuum matching the formation of the organic layer 24 by flash evaporation, the inorganic layer formation section 42 is reduced by the vacuum evacuation means 62 to a given degree of vacuum matching the formation of the inorganic layer 20, and the surface roughening section 46 is reduced by the vacuum evacuation means 72 to a given degree of vacuum matching the back-sputtering treatment. The feed chamber 12 is reduced by the vacuum evacuation means 35 to a given degree of vacuum; the take-up chamber 16 is reduced by the vacuum evacuation means 96 to a given degree of vacuum.

The shower head electrode 56 in the inorganic layer formation section 42 is supplied from the feed gas supply section 58 with a feed gas matching the inorganic layer 20 to be formed; the shower head electrode 64 in the surface roughening section 64 is supplied from the sputter gas supply section 68 with a feed gas for the back-sputtering treatment.

When the supply amounts of the feed gas and the sputter gas and the degrees of vacuum of the inorganic layer formation section 42, the surface roughening section 46, and the organic layer formation section 48 have stabilized, the RF power source 60 supplies the shower head electrode 56 with plasma excitation power, the DC pulse power source 70 supplies the shower head electrode 64 with plasma excitation power, and the organic layer material evaporation section 78 starts spraying the organic compound, which is to be formed into the organic layer 24, onto the organic layer material evaporation section 74 (heating nozzle 74b), whereas the curing section 76 starts radiating UV light.

In the illustrated production device 10, the drum 52 serves as a counter electrode so that the drum 52 forms an electrode pair with the shower head electrode 56 in CCP-CVD and the drum 52 forms an electrode pair with the shower head electrode 64 for the back-sputtering treatment, as described earlier.

Thus, the substrate Z, passed over the drum 52, travels in the longitudinal direction to sequentially undergo formation of the inorganic layer 20 thereon by CCP-CVD in the inorganic layer formation section 42, surface roughening treatment applied to the surface of the inorganic layer 20 by back-sputtering treatment in the surface roughening section 46, and formation of the organic layer 24 on the surface of the inorganic layer 20 in the organic layer formation section 48, thereby forming the gas barrier laminate according to the invention by the production method of the invention.

The substrate Z, now formed with the gas barrier laminate composed of the inorganic layer 20 and the organic layer 24 in the film deposition chamber 14, is guided through the guide roller 50 and admitted through a slit 92a into the take-up chamber 16 that is separated from the film deposition chamber 14 by a separation wall 92. In the illustrated embodiment, the take-up chamber 16 includes the guide roller 94, the take-up shaft 36, and the vacuum evacuation means 96.

The substrate Z formed with the gas barrier laminate and admitted in the take-up chamber 16 is guided to the take-up shaft 36, whereby the substrate Z is wound to form a roll and supplied as an intermediate product of gas barrier film, for example, to a next step.

The take-up chamber 16 is also provided with the vacuum evacuation means 96 as in the above-described feed chamber 12, and during formation of the gas barrier laminate, its pressure is reduced to a degree of vacuum suitable for the film deposition pressure in the film deposition chamber 14.

The above-described embodiment refers to a case where the method of producing the gas barrier laminate in the present invention is applied to a roll-to-roll type device. However, this is not the sole case of the present invention and as described above, the gas barrier laminate may be formed on substrate sheets, optical devices such as lenses and displays, and solar cells. Thus, the present invention may be used for a so-called batch type production of a gas barrier laminate.

While the method for forming the gas barrier laminate according to the invention and the gas barrier laminate formed by the same method have been described above in detail, the present invention is by no means limited to the foregoing embodiments and it should be understood that various improvements and modifications may of course be made without departing from the gist of the present invention.

### EXAMPLES

### Example 1

The substrate Z used was a 100-μm thick PEN film (Q65FA provided by Teijin DuPont Films Japan Limited) coated thereon with a 500-nm thick organic layer of trimethylolpropane triacrylate.

The organic layer was formed in the same manner as the organic layer 24 described later.

A 60-nm thick silicon nitride film was formed as the inorganic layer 20 on the surface of the substrate Z using a CCP-CVD technique.

Feed gases used were silane gas (SiH₄), ammonia gas (NH₃), nitrogen gas (N2), and hydrogen gas (H₂). The flow rates were 100 ml/min for the silane gas and the ammnonia gas, 850 ml/min for the nitrogen gas, and 350 ml/min for the hydrogen gas.

The film deposition pressure used was 80 Pa; the plasma excitation power used was 13.56 MHz, 160 W.

Then, back-sputtering treatment was applied to the surface of the inorganic layer 20 formed on the substrate Z to roughen the surface of the inorganic layer 20.

Ar gas was used as sputter gas; its flow rate was 30 ml/min.

The pressure was set to 2 Pa. The plasma excitation power applied to the electrode was −200-V DC pulse voltage. The treatment was applied for 30 s.

The average surface roughness Ra of the inorganic layer 20 measured 1.5 nm before the surface roughening treatment and 30 nm after the treatment.

Then, a liquid organic film was formed by flash evaporation on the surface-roughened inorganic layer 20, and the liquid film was irradiated with ultraviolet light to cure the organic compound and form a 250-nm thick organic layer 24 on the inorganic layer 20, thereby fabricating a gas barrier film having a gas barrier laminate of the invention formed on the substrate Z.

The liquid organic compound, raw material, was a composite of 98 wt % of trimethylolpropane triacrylate, a monomer, provided by Kyoeisha Chemical Co., Ltd., and a 2 wt % of a mixture of 2,4,6-trimethylbenzophenone and 4-methylbenzophenone (provided by Nihon Siberhegner Kabushiki Kaisha, ESACURE TZT) as a polymerization initiator.

The pressure applied by the syringe pump to feed the liquid organic compound was 130 PSI; the flow rate was 3 ml/min.

The pressure inside the liquid-propelling section (heating chamber) was 2×10⁻² Pa, the temperature of the heating plate was 200° C., and the output power of the ultrasonic wave at the liquid droplet injection port for injecting droplets to the liquid-propelling section was 7 W.

The substrate Z was kept at a temperature of 15° C. during flash evaporation.

Ultraviolet light having a luminance of 70 mW/cm₂ was radiated for 10 s.

### Example 2

The inorganic layer 20 and the organic layer 24 were formed on the surface of the substrate Z to fabricate a gas barrier film in exactly the same manner as in Example 1 except that the thickness of the inorganic layer 20 was 30 nm.

The average surface roughness Ra of the inorganic layer 20 measured 1.5 nm before the surface roughening treatment and 15 nm after the treatment.

### Comparative Example 1

The inorganic layer 20 and the organic layer 24 were formed on the surface of the substrate Z to fabricate a gas barrier film in exactly the same manner as in Example 1 except that no surface roughening treatment using the back-sputtering was applied to the inorganic layer 20.

### Comparative Example 2

The inorganic layer 20 and the organic layer 24 were formed on the surface of the substrate Z to fabricate a gas barrier film in exactly the same manner as in Example 1 except that plasma treatment was applied in lieu of the back-sputtering treatment to the surface of the inorganic layer 20.

The plasma treatment was effected using Ar gas (flow rate 15 ml/min), O₂ gas (flow rate 5 ml/min), and N₂ gas (flow rate 5 ml/min), and with a pressure of 5 Pa and a plasma excitation power having a frequency of 13.56 MHz, 50 W.

### Comparative Example 3

The liquid organic compound, raw material, was a composite of 88 wt % of trimethylolpropane triacrylate, a monomer, provided by Kyoeisha Chemical Co., Ltd., 10 wt % of KBM5103 provided by Shin-Etsu Chemical Co., Ltd, and a 2 wt % of a mixture of 2,4,6-trimethylbenzophenone and 4-methylbenzophenone (provided by NihonSiberhegner Kabushiki Kaisha, ESACURE TZT) as a polymerization initiator to fabricate a gas barrier film in exactly the same manner as in Example 1 except that no surface roughening treatment using the back-sputtering was applied to the inorganic layer 20.

The four different gas barrier films thus fabricated were examined for gas barrier properties and adhesion between the inorganic layer 20 and the organic layer 24.

[Gas Barrier Properties]

The moisture vapor transmission rate [g/(m₂·day)] of the gas barrier films was measured by the calcium corrosion method (a method described in JP 2005-283561 A).

Gas barrier films having a moisture vapor transmission rate of 1.0×10⁻² or more were rated “poor”;

gas barrier films having a moisture vapor transmission rate in a range of 1.0×10⁻⁵ inclusive to 1.0×10⁻² were rated “good”; and

gas barrier films having gas barrier properties of less than 1.0×10⁻⁵ were rated “excellent”.

[Adhesion]

The organic layer 24 was cut to 100 squares, each measuring 1 mm×1 mm, and subjected to a 180° -peel test using a tape according to JIS K5400 to measure persistence.

Gas barrier films retaining 100% of the organic layer 24 was rated “good”;

gas barrier films retaining about 50% of the organic layer 24 was rated “fair”; and

gas barrier films of which the whole organic layer 24 peeled was rated “poor”.

The adhesion was measured immediately after fabrication and one week thereafter.

[Comprehensive Evaluation]

Gas barrier films having gas barrier properties rated “excellent” or “good” and an adhesion rated “good” or “fair” were rated “good”;

gas barrier films having gas barrier properties, adhesion, or both rated “poor” were rated “poor”.

The results are shown in Table 1.

TABLE 1

| | Gas barrier | Adhesion | | |
|---|---|---|---|---|
| | properties | Immediately | One week | |
| | [g/(m2 · | after | after | Overall |
| | day)] | fabrication | fabrication | rating |
| Ex. 1 | Good | Good | Good | Good |
| Ex. 2 | Excellent | Good | Fair | Good |
| Comp. Ex. 1 | Good | Poor | Poor | Poor |
| Comp. Ex. 2 | Poor | Good | Poor | Poor |
| Comp. Ex. 3 | Good | Fair | Poor | Poor |

According to the invention where the organic layer 24 is formed after the inorganic layer 20 is subjected to surface roughening treatment, a gas barrier laminate having excellent gas barrier properties and adhesion between the organic layer 24 and the inorganic layer 20 can be fabricated as shown in the above table.

While Comparative Examples 1 and 3, not subjected to surface roughening treatment, had good gas barrier properties, they have a poor adhesion; while Comparative Example 2, of which the organic layer 24 was subjected to plasma treatment, had a good adhesion, their adhesion decreased with time and their gas barrier properties were not sufficient.

The above results clearly show the beneficial effects of the present invention.

Thus, the method of producing the gas barrier laminate according to the invention may be favorably used to fabricate a variety of products involving inorganic/organic gas barrier laminates that are required to maintain high gas barrier properties over a long period of time.

What is claimed is:

1. A method of producing a gas barrier laminate comprising the steps of:
forming an inorganic compound layer on a substrate by vapor-phase film deposition,
applying surface roughening treatment to a surface of the inorganic compound layer, and
subsequently forming an organic compound layer on the roughened surface of the inorganic compound layer by flash evaporation.

2. The method of producing a gas barrier laminate according to claim 1, wherein the surface roughening treatment is applied by back-sputtering treatment.

3. The method of producing a gas barrier laminate according to claim 2, wherein the back-sputtering treatment is applied using one or more gases selected from the group consisting of Ar gas, He gas, Ne gas, Kr gas, Xe gas, Rn gas and N₂ gas.

4. The method of producing a gas barrier laminate according to claim 1, wherein the surface of the inorganic compound layer is roughened to mean surface roughness Ra of 10 nm to 100 nm by the surface roughening treatment.

5. The method of producing a gas barrier laminate according to claim 1, wherein the substrate has a surface formed of an organic compound on which the inorganic compound layer is formed.

6. The method of producing a gas barrier laminate according to claim 5, wherein the organic compound forming the surface of the substrate is formed by flash evaporation.

7. The method of producing a gas barrier laminate according to claim 1, wherein the substrate has a long length and is passed over a peripheral surface of a cylindrical drum, the method comprising, sequentially, transporting the substrate in a longitudinal direction, forming the inorganic compound layer by using a vapor-phase film deposition means provided opposite the peripheral surface of the drum, performing the surface roughening treatment on the inorganic compound layer by using a surface roughening means provided opposite the peripheral surface of the drum, and forming the organic compound layer by using by using a first flash evaporation means provided opposite the peripheral surface of the drum and downstream of the film deposition means in the direction in which the substrate is transported.

8. The method of producing a gas barrier laminate according to claim 7, wherein an organic compound layer is formed on the substrate by a second flash evaporation means provided opposite the peripheral surface of the drum and upstream of the film deposition means in the direction in which the substrate is transported before the inorganic compound layer is formed.

9. The method of producing a gas barrier laminate according to claim 1, wherein the inorganic compound layer is formed by plasma-enhanced CVD.
